(19) United States
(12) Patent Application Publication
(10) Pub. No.: US 2016/0041316 A1
(43) Pub. Date: Feb. 11, 2016

(54) DISPLAY SUBSTRATE AND MANUFACTURING METHOD THEREOF, AND DISPLAY APPARATUS

(71) Applicants: BOE TECHNOLOGY GROUP CO., LTD., Beijing (CN); BEIJING BOE DISPLAY TECHNOLOGY CO., LTD., Beijing (CN)

(72) Inventor: Dong WANG, Beijing (CN)

(21) Appl. No.: 14/568,803

(22) Filed: Dec. 12, 2014

(30) Foreign Application Priority Data
Aug. 8, 2014 (CN) 201410389604.X

(51) Int. Cl. G02B 5/20; H01L 27/12

(52) U.S. Cl. CPC G02B 5/20; H01L 27/124

(57) ABSTRACT

The present invention provides a display substrate and a manufacturing method thereof, and a display apparatus. The display substrate comprises a base substrate and a black matrix provided above the base substrate, the black matrix comprises a first black matrix and a second black matrix, the first black matrix and the second black matrix are intersected with each other, a photo spacer is provided over the first black matrix, wherein, the first black matrix comprises a non-spacer part not provided correspondingly to the photo spacer and a spacer part provided correspondingly to the photo spacer, and the non-spacer part has a line width smaller than width of the spacer part. In the present invention, the line width of the non-spacer part is reduced, the first black matrix will have a reduced area, that is, shading area of the first black matrix is reduced, and transmittance of the manufactured product is improved.

### CROSS-REFERENCE TO RELATED APPLICATION

This application claims priority to Chinese Patent Application No. 201410389604.X, filed on Aug. 8, 2014 in the Chinese Intellectual Property Office, the disclosure of which is incorporated by reference herein in its entirety.

### FIELD OF THE INVENTION

The present invention relates to the field of display technology, and particularly, to a display substrate and manufacturing method thereof, and a display apparatus comprising the display substrate.

### BACKGROUND OF THE INVENTION

Liquid crystal display apparatuses are currently the most commonly used panel display apparatuses, wherein thin film transistor liquid crystal display (TFT-LCD) apparatuses are the mainstream products of the liquid crystal display apparatuses. A liquid crystal display panel is an import member of a liquid crystal display apparatus. The liquid crystal display panel is formed by aligning an array substrate with a color filter substrate to form a cell and filling liquid crystal between the array substrate and the color filter substrate. FIG. 1 shows a structural diagram of a color filter substrate in the prior art, and FIG. 2 shows a sectional view of the color filter substrate of FIG. 1 taken along line A-A. As shown in FIGS. 1 and 2, the color filter substrate comprises a base substrate 11, a black matrix 12, a color matrix pattern and a covering layer 13. The black matrix 12 and the color matrix pattern are provided above the base substrate 11, and the black matrix 12 is provided below the color matrix pattern. The covering layer 13 is provided above the color matrix pattern. Further, a back electrode layer 14 is formed on a back side of the base substrate 11. Further, a photo spacer (PS) 15 is formed on the covering layer 13, and the photo spacer 15 is provided over the black matrix 12. The color matrix pattern may comprise red patterns R, green patterns G and blue patterns B which are sequentially arranged to form the color matrix pattern. The black matrix 12 may comprise a gate line black matrix 121 and a data black matrix 122. The gate line black matrix 121 is provided transversely, the data black matrix 122 is provided longitudinally, and the gate line black matrix 121 and the data black matrix 122 are intersected with each other. The array substrate comprises a gate line and a data line. The gate line black matrix 121 is a black matrix corresponding to the gate line, and the data black matrix 122 is a black matrix corresponding to the data line. The photo spacer 15 is provided over the gate line black matrix 121. Each of the gate line black matrix 121 and the data black matrix 122 is of a structure of strips.

FIG. 3 shows a diagram of dimensions of the black matrix and the photo spacer in the color filter substrate of FIG. 1, and FIG. 4 shows a diagram of dimension of the black matrix in FIG. 3. As shown in FIGS. 3 and 4, A=C0+C1+C2, wherein A denotes a line width of the gate line black matrix 121, C0 denotes a bottom width of the photo spacer 15, C1 denotes the minimum distance between a bottom edge of the photo spacer 15 and an upper edge of the corresponding gate line black matrix 121, C2 denotes the minimum distance between the bottom edge of the photo spacer 15 and a lower edge of the corresponding gate line black matrix 121. FIG. 5 shows a diagram of an oblique photo spacer. As shown in FIG. 5, the photo spacer 15 provided over the gate line black matrix 121 is oblique. In order to ensure stability of the photo spacer 15 and prevent the photo spacer 15 from being oblique, a line width of the gate line black matrix 121 may be set as A=C0+C1+C2 (C1≧D and C2≧D) while designing dimensions of the gate line black matrix 121 and the photo spacer 15, wherein D denotes a dimension margin of the gate line black matrix 121, and usually D=\sqrt{E1²+E2²+E3²+E4²}, wherein E1 denotes fluctuation of the line width of the gate line black matrix 121, E2 denotes a slope angle of the black matrix 12 (the black matrix usually has a longitudinal section in an isosceles trapezoid shape, and the slope angle denotes a trapezoid angle of the isosceles trapezoid), E3 denotes fluctuation of the bottom width of the photo spacer 15, and E4 denotes location accuracy of the photo spacer 15.

Since A=C0+C1+C2 (C1≧D and C2≧D), A≧C0+2D. In order to ensure stability of the photo spacer 15, D will be increased. With increasing of D, A will also be increased. Since the gate line black matrix 121 is of a structure of strips, when the line width A of the gate line black matrix 121 is increased, area of the gate line black matrix 121 will also be increased, the gate line black matrix 121 will have an increased shading area, and a manufactured product (e.g., a display apparatus) with a lower transmittance will be obtained.

### SUMMARY OF THE INVENTION

An object of the present invention is to provide a display substrate and a manufacturing method thereof, and a display apparatus for improving transmittance of the manufactured product.

In order to achieve the above object, the present invention provides a display substrate comprising a base substrate and a black matrix provided above the base substrate, the black matrix comprises a first black matrix and a second black matrix, the first black matrix and the second black matrix are intersected with each other, a photo spacer is provided over the first black matrix, the first black matrix comprises a non-spacer part not provided correspondingly to the photo spacer and a spacer part provided correspondingly to the photo spacer, and the non-spacer part has a line width smaller than width of the spacer part.

Optionally, the minimum distances in all directions between a bottom edge of the photo spacer and an edge of the corresponding spacer part are equal to each other.

Optionally, widths of the spacer part in all directions are equal to each other.

Optionally, the edge of the spacer part is curve.

Optionally, the minimum distance between the bottom edge of the photo spacer and the edge of the corresponding spacer part is larger than or equal to 5 μm.

Optionally, the minimum distance between the bottom edge of the photo spacer and the edge of the corresponding spacer part is larger than or equal to a dimension margin of the first black matrix.

In order to achieve the above object, the present invention further provides a display apparatus comprising a display substrate and an opposite substrate provided oppositely to each other, wherein the display substrate is the above display substrate.

Optionally, the display substrate is a color filter substrate, and the opposite substrate is an array substrate, the array substrate comprises a gate line and a data line, the first black matrix is a gate line black matrix provided correspondingly to the gate line, and the second black matrix is a data line black matrix provided correspondingly to the data line; or the display substrate is a color filter array substrate, and the opposite substrate is a transparent substrate, the color filter array substrate comprises a gate line and a data line, the first black matrix is a gate line black matrix provided correspondingly to the gate line, and the second black matrix is a data line black matrix provided correspondingly to the data line.

In order to achieve the above object, the present invention further provides a manufacturing method of display substrate comprising: forming a black matrix above a base substrate, the black matrix comprising a first black matrix and a second black matrix, the first black matrix and the second black matrix being intersected with each other; forming a photo spacer above the first black matrix, the first black matrix comprising a non-spacer part not provided correspondingly to the photo spacer and a spacer part provided correspondingly to the photo spacer, the non-spacer part having a line width smaller than width of the spacer part.

Optionally, the step of forming a black matrix above a base substrate comprises: forming a black matrix material layer over the base substrate; applying photoresist on the black matrix material layer; performing exposure on the photoresist through a mask so as to form a photoresist reserve part and a photoresist removal part, the mask comprising an open region and a light shading region; performing development on the exposure photoresist to remove the photoresist removal part and reserve the photoresist reserve part; etching the black matrix material layer above the base substrate to form the first black matrix and the second black matrix; and stripping off the photoresist reserve part.

The present invention has following beneficial effects.

In the display substrate and the manufacturing method thereof, and the display apparatus of the present invention, the first black matrix comprises the non-spacer part not provided correspondingly to the photo spacer and the spacer part provided correspondingly to the photo spacer, and the line width of the non-spacer part is smaller than the width of the spacer part, thus the line width of the non-spacer part is reduced, the first black matrix will have a reduced area, that is, shading area of the first black matrix is reduced, thereby transmittance of the manufactured product is improved.

### BRIEF DESCRIPTION OF THE DRAWINGS

FIG. 1 shows a structural diagram of a color filter substrate in the prior art.

FIG. 2 shows a sectional view of the color filter substrate of FIG. 1 taken along line A-A.

FIG. 3 shows a diagram of dimensions of the black matrix and the photo spacer in the color filter substrate of FIG. 1.

FIG. 4 shows a diagram of dimension of the black matrix in FIG. 3.

FIG. 5 shows a diagram of an oblique photo spacer.

FIG. 6 shows a structural diagram of a display substrate in accordance with a first embodiment of the present invention.

FIG. 7 shows a structural diagram of a black matrix in FIG. 6.

FIG. 8 shows a flowchart of a manufacturing method of display substrate in accordance with a third embodiment of the present invention.

FIG. 9 shows a structural diagram of a mask used in the manufacturing method of FIG. 8.

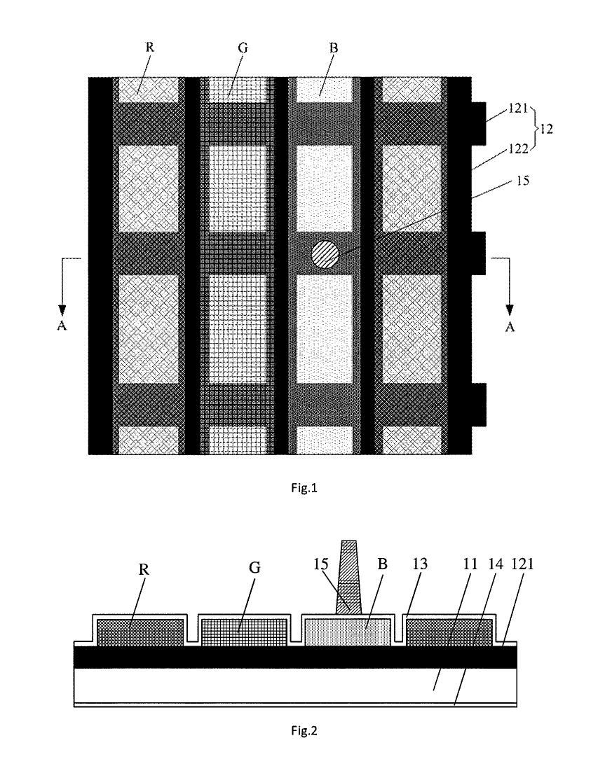

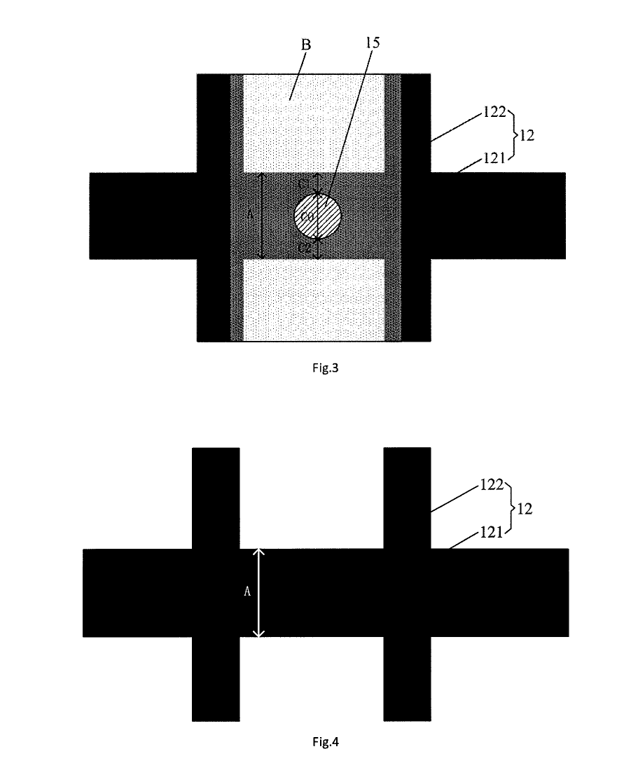

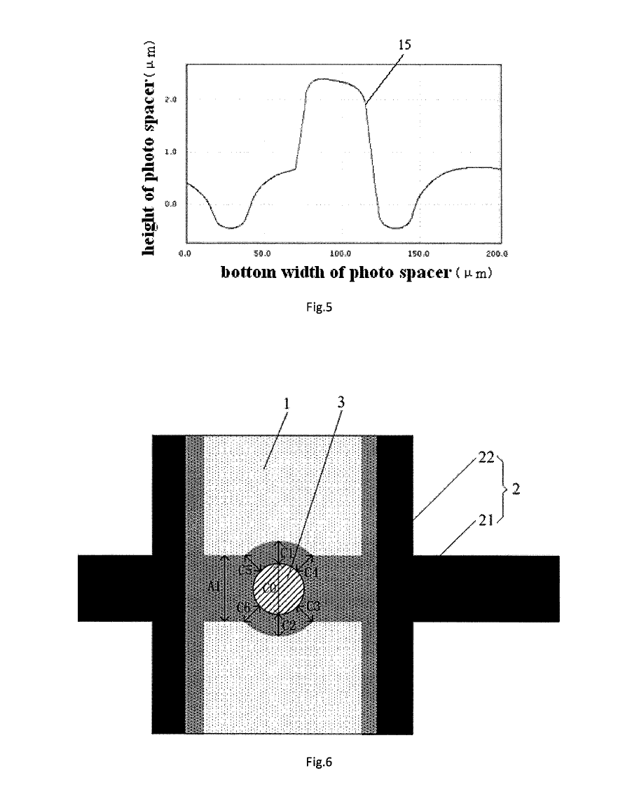

### DETAILED DESCRIPTION OF EMBODIMENTS

Hereinafter, the display substrate and the manufacturing method thereof, and the display apparatus of the present invention will be described in detail in conjunction with accompanying drawings so that persons skilled in the art can understand technical solutions of the present invention better.

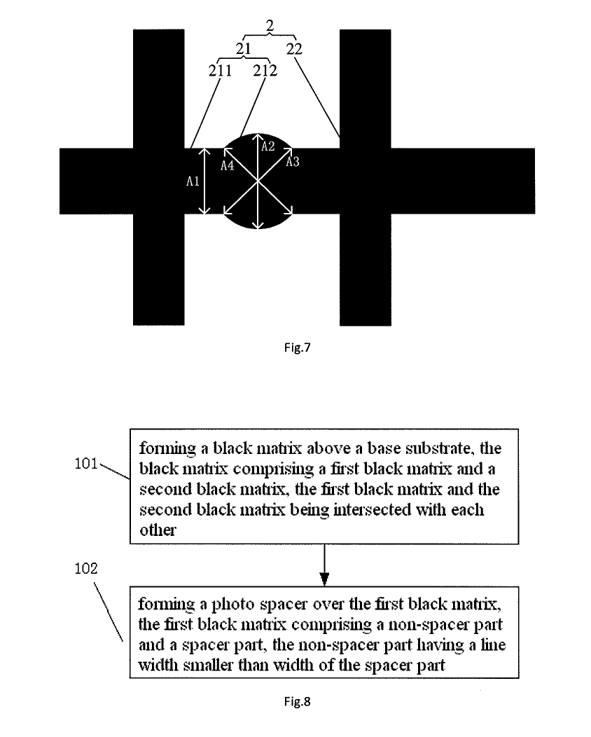

FIG. 6 shows a structural diagram of a display substrate in accordance with a first embodiment of the present invention, and FIG. 7 shows a structural diagram of a black matrix in FIG. 6. As shown in FIGS. 6 and 7, the display substrate comprises a base substrate (not shown) and a black matrix 2 provided above the base substrate, the black matrix 2 comprises a first black matrix 21 and a second black matrix 22, the first black matrix 21 and the second black matrix 22 are intersected with each other, a photo spacer 3 is provided over the first black matrix 21, the first black matrix 21 comprises a non-spacer part 211 not provided correspondingly to the photo spacer 3 and a spacer part 212 provided correspondingly to the photo spacer 3, and the non-spacer part 211 has a line width smaller than width of the spacer part 212. It can be understood that, although only one photo spacer 3 is shown in the Figs., a plurality of photo spacers 3 may be provided, and the number of the photo spacers 3 is not limited. Correspondingly, the first black matrix 21 may comprise a plurality of non-spacer parts 211 and a plurality of spacer parts 212.

In the present embodiment, the display substrate is a color filter substrate. In this case, the display substrate further comprises a color matrix pattern 1 provided above the black matrix 2. The first black matrix 21 and the second black matrix 22 are longitudinally and transversely intersected to each other. Specifically, the first black matrix 21 is provided transversely, and the second black matrix 22 is provided longitudinally.

A covering layer (not shown) is further formed above the color matrix pattern 1, and the photo spacer 3 is provided on the covering layer. Specifically, the photo spacer 3 is provided over the spacer part 212 of the first black matrix 21, thus the photo spacer 3 corresponds to the spacer part 212.

The spacer part 212 has a width larger than bottom width of the photo spacer 3. It should be noted that, as shown in FIG. 7, the maximum width A2 of the spacer part 212 in the vertical direction is usually set as the width of the spacer part 212. As shown in FIGS. 6 and 7, the width of the spacer part 212 is A2=C1+C2+C0, wherein C1 denotes the minimum distance between a bottom edge of the photo spacer 3 and an upper edge of the corresponding spacer part 212, C2 denotes the minimum distance between the bottom edge of the photo spacer 3 and a lower edge of the corresponding spacer part 212, C0 denotes the bottom width of the photo spacer 3. The width A2 is set so that A2=C1+C2+C0>A1, wherein A1 denotes line width of the non-spacer part 211. The spacer part 212 is connected with the non-spacer part 211. In order to coordinate with shape of the photo spacer 3, the spacer part 212 may have a curve edge. The non-spacer part 211 has a straight line edge, that is, the non-spacer part 211 is of a strip shape.

Preferably, the minimum distances in all directions between the bottom edge of the photo spacer 3 and the edge of the corresponding spacer part 212 are equal to each other, so as to ensure stability of the photo spacer and prevent the photo spacer from being oblique. As shown in FIGS. 6 and 7, all of C1, C2, C3, C4, C5 and C6 are equal to each other, wherein C3 denotes the minimum distance between the bottom edge of the photo spacer 3 and a lower right edge of the corresponding spacer part 212, C4 denotes the minimum distance between the bottom edge of the photo spacer 3 and an upper right edge of the corresponding spacer part 212, C5 denotes the minimum distance between the bottom edge of the photo spacer 3 and an upper left edge of the corresponding spacer part 212, and C6 denotes the minimum distance between the bottom edge of the photo spacer 3 and a lower left edge of the corresponding spacer part 212. Seen from FIGS. 6 and 7, the line width of the non-spacer part 211 at left side of the spacer part 212 is smaller than the width of the spacer part 212, and the line width of the non-spacer part 211 at right side of the spacer part 212 is smaller than the width of the spacer part 212, thus the shading area of the first black matrix is reduced, while the stability of the photo spacer 3 can be ensured.

Preferably, widths of the spacer part 212 in all directions are equal to each other. As shown in FIG. 7, A2, A3 and A4 are equal to each other, wherein A2 denotes a width of the spacer part 212 in the vertical direction, each of A3 and A4 denotes a width of the spacer part 212 in a direction at a certain angle with respect to the vertical direction. Thus, in the present embodiment, it can say that each of A2, A3 and A4 denotes the width of the spacer part 212.

In order to reduce shading area of the black matrix 2 (in particular, the first black matrix 21), the minimum distance between the bottom edge of the photo spacer 3 and the edge of the corresponding spacer part 212 may be set as a minimum value which can ensure the stability of the photo spacer 3. Preferably, the minimum distance between the bottom edge of the photo spacer and the edge of the corresponding spacer part is larger than or equal to 5 μm.

Preferably, the minimum distance between the bottom edge of the photo spacer 3 and the edge of the corresponding spacer part 212 is larger than or equal to a dimension margin of the first black matrix 21, that is, C1≧D, C2≧D, C3≧D, C4≧D, C5≧D, and C6≧D, wherein D is the dimension margin of the first black matrix 21.

In the present embodiment, the display substrate is a color filter substrate. When the display substrate is applied in a display apparatus, the display apparatus may further comprises an array substrate provided oppositely to the display substrate. The array substrate comprises a gate line and a data line. In this case, the first black matrix 21 is a gate line black matrix provided correspondingly to the gate line, and the second black matrix 22 is a data line black matrix provided correspondingly to the data line.

In the display substrate of the present embodiment, the first black matrix comprises the non-spacer part not provided correspondingly to the photo spacer and the spacer part provided correspondingly to the photo spacer, and the line width of the non-spacer part is smaller than the width of the spacer part, thus the line width of the non-spacer part is reduced, the first black matrix will have a reduced area, that is, shading area of the first black matrix is reduced, thereby transmittance of the manufactured product is improved. Along with a requirement for a higher resolution of a product, a black matrix in a display substrate should have a line width as smaller as possible. An obvious effect will be obtained by applying the display substrate of the present embodiment in a product with a high resolution.

A second embodiment of the present invention provides a display apparatus. The display apparatus comprises a display substrate and an opposite substrate provided oppositely to each other. The display substrate may be the display substrate of the first embodiment, which will not be described in detail here.

Optionally, the display substrate is a color filter substrate, and the opposite substrate is an array substrate, wherein the array substrate comprises a gate line and a data line. In this case, the first black matrix is a gate line black matrix provided correspondingly to the gate line, and the second black matrix is a data line black matrix provided correspondingly to the data line.

Optionally, the display substrate is a color filter array substrate (i.e., color filter on array), and the opposite substrate is a transparent substrate. For example, the transparent substrate may be a glass substrate or a sapphire substrate, wherein the color filter array substrate further comprises a gate line and a data line. In this case, the first black matrix is a gate line black matrix provided correspondingly to the gate line, and the second black matrix is a data line black matrix provided correspondingly to the data line.

In the display apparatus of the present embodiment, the first black matrix comprises the non-spacer part not provided correspondingly to the photo spacer and the spacer part provided correspondingly to the photo spacer, and the line width of the non-spacer part is smaller than the width of the spacer part, thus the line width of the non-spacer part is reduced, the first black matrix will have a reduced area, that is, shading area of the first black matrix is reduced, thereby transmittance of the manufactured product is improved. Along with a requirement for a higher resolution of a product, a black matrix in a display substrate should have a line width as smaller as possible. An obvious effect will be obtained by applying the display substrate of the present embodiment in a product with a high resolution.

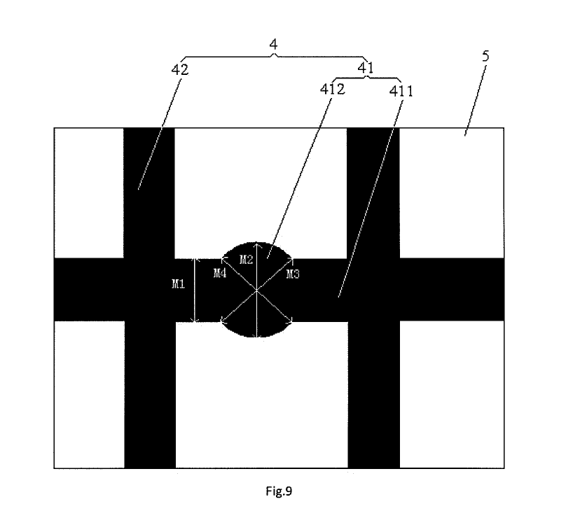

FIG. 8 shows a flowchart of a manufacturing method of display substrate in accordance with a third embodiment of the present invention. As shown in FIG. 8, the manufacturing method comprises following steps 101 and 102.

Step 101: forming a black matrix above a base substrate, the black matrix comprising a first black matrix and a second black matrix, the first black matrix and the second black matrix being intersected with each other.

Specifically, the step 101 may comprise following sub-steps 1011 to 1016.

Sub-step 1011: forming a black matrix material layer above the base substrate.

Sub-step 1012: applying photoresist on the black matrix material layer.

Sub-step 1013: performing exposure on the photoresist through a mask so as to form a photoresist reserve part and a photoresist removal part. Specifically, the mask comprises an open region and a light shading region. As an example, when positive photoresist is used, the light shading region may comprise a first light shading sub-region and a second light shading sub-region. The first light shading sub-region is used for forming the first black matrix, and the second light shading sub-region is used for forming the second black matrix. The first black matrix has a line width substantially corresponding to line width of the first light shading sub-region, and the second black matrix has a line width substantially corresponding to line width of the second light shading sub-region.

FIG. 9 shows a structural diagram of a mask used in the sub-step 1013. As shown in FIG. 9, the mask comprises a light shading region 4 and an open region 5. The light shading region 4 comprises a first light shading sub-region 41 and a second light shading sub-region 42. The first light shading sub-region 41 is used for forming the first black matrix 21, and the second light shading sub-region 42 is used for forming the second black matrix 22. The first light shading sub-region 41 may comprise a non-spacer region 411 and a spacer region 412. The non-spacer region 411 is used for forming the non-spacer part 211, and the spacer region 412 is used for forming the spacer part 212. The line width of the first black matrix 21 substantially corresponds to the line width of the first light shading sub-region 41, and the line width of the second black matrix 22 substantially corresponds to the line width of the second light shading sub-region 42. However, since there may be a bias for a line width of the photoresist reserve part formed through the mask in the sub-step 1013, specifically, as shown in FIGS. 7 and 9, the line width of the non-spacer part 211 of the first black matrix 21 may be formed as A1=M1+N, the width of the spacer part 212 may be formed as A2=M2+N, A3=M3+N, A4=M4+N, wherein M1 denotes line width of the non-spacer region 411 of the first light shading sub-region 41, M2, M3 and M4 denote widths of the spacer region 412 of the first light shading sub-region 41 in different directions, N denotes the bias of the line width of the photoresist reserve part. Preferably, M2, M3 and M4 are equal to each other.

After performing exposure on the positive photoresist through the mask shown in FIG. 9, the photoresist corresponding to the light shading region 4 becomes the photoresist reserve part, and the photoresist corresponding to the open region 5 becomes the photoresist removal part.

It should be understood that, although the example that the positive photoresist is used is described above, it may be possible to use negative photoresist. In a case of using the negative photoresist, a following mask may be used. The mask comprises a light shading region and an open region, and the open region may comprise a first open sub-region for forming the first black matrix 21 and a second open sub-region for forming the second black matrix 22. After performing exposure on the negative photoresist through the mask, the photoresist corresponding to the open region becomes the photoresist reserve part, and the photoresist corresponding to the light shading region becomes the photoresist removal part. That is, the photoresist in the same shape as that of the black matrix to be formed will be reserved. In addition, dimensions of all parts of the black matrix formed by using the mask may be referred to dimensions of all parts of the black matrix formed by using the mask shown in FIG. 9, which will not be described in detail here.

Sub-step 1014: performing development on the photoresist subjected to the exposure so as to remove the photoresist removal part and reserve the photoresist reserve part. In a case of performing exposure on the positive photoresist through the mask shown in FIG. 9, after performing development, the photoresist corresponding to the light shading region 4 will be reserve, and the photoresist corresponding to the open region 5 will be removed. That is, the photoresist in the same shape as that of the black matrix (the first black matrix 21 and the second black matrix 22) to be formed will be reserved.

Sub-step 1015: etching the black matrix material layer above the base substrate to form the first black matrix and the second black matrix.

Sub-step 1016: stripping off the photoresist reserve part.

Step 102: forming a photo spacer over the first black matrix, the first black matrix comprises a non-spacer part not provided correspondingly to the photo spacer and a spacer part provided correspondingly to the photo spacer, the non-spacer part has a line width smaller than width of the spacer part.

In the present embodiment, if the display substrate to be formed is a color filter substrate, the manufacturing method will further comprise following steps before the step 102: forming a color matrix pattern above the base substrate, the color matrix pattern being provided above the black matrix; and forming a covering layer above the color matrix pattern. Thus, the photo spacer is provided on the covering layer.

The manufacturing method of the present embodiment may be used for manufacturing the display substrate of the first embodiment.

In the manufacturing method of the present embodiment, the first black matrix comprises the non-spacer part not provided correspondingly to the photo spacer and the spacer part provided correspondingly to the photo spacer, and the line width of the non-spacer part is smaller than the width of the spacer part, thus the line width of the non-spacer part is reduced, the first black matrix will have a reduced area, that is, shading area of the first black matrix is reduced, thereby transmittance of the manufactured product is improved. Along with a requirement for a higher resolution of a product, a black matrix in a display substrate should have a line width as smaller as possible. An obvious effect will be obtained by applying the display substrate of the present embodiment in a product with a high resolution.

It should be understood that, the above embodiments are only used to explain the principle of the present invention, but not to limit the present invention. A person skilled in the art can make various variations and modifications without departing from spirit and scope of the present invention, and the variations and the modifications are also considered to be within the protection scope of the present invention.

1. A display substrate comprising a base substrate and a black matrix provided above the base substrate, the black matrix comprising a first black matrix and a second black matrix, the first black matrix and the second black matrix being intersected with each other, a photo spacer being provided over the first black matrix, wherein, the first black matrix comprises a non-spacer part not provided correspondingly to the photo spacer and a spacer part provided correspondingly to the photo spacer, and the non-spacer part has a line width smaller than width of the spacer part.

2. The display substrate of claim 1, wherein the minimum distances in all directions between a bottom edge of the photo spacer and an edge of the corresponding spacer part are equal to each other.

3. The display substrate of claim 1, wherein widths of the spacer part in all directions are equal to each other.

4. The display substrate of claim 1, wherein the edge of the spacer part is curve.

5. The display substrate of claim 1, wherein the minimum distance between the bottom edge of the photo spacer and the edge of the corresponding spacer part is larger than or equal to 5 μm.

6. The display substrate of claim 1, wherein the minimum distance between the bottom edge of the photo spacer and the edge of the corresponding spacer part is larger than or equal to a dimension margin of the first black matrix.

7. A display apparatus comprising a display substrate and an opposite substrate provided oppositely to each other, the display substrate comprising a base substrate and a black matrix provided above the base substrate, the black matrix comprising a first black matrix and a second black matrix, the first black matrix and the second black matrix being intersected with each other, a photo spacer being provided over the first black matrix, wherein, the first black matrix comprises a non-spacer part not provided correspondingly to the photo spacer and a spacer part provided correspondingly to the photo spacer, and the non-spacer part has a line width smaller than width of the spacer part.

8. The display apparatus of claim 7, wherein the minimum distances in all directions between a bottom edge of the photo spacer and an edge of the corresponding spacer part are equal to each other.

9. The display apparatus of claim 7, wherein widths of the spacer part in all directions are equal to each other.

10. The display apparatus of claim 7, wherein the edge of the spacer part is curve.

11. The display apparatus of claim 7, wherein the minimum distance between the bottom edge of the photo spacer and the edge of the corresponding spacer part is larger than or equal to 5 μm.

12. The display apparatus of claim 7, wherein the minimum distance between the bottom edge of the photo spacer and the edge of the corresponding spacer part is larger than or equal to a dimension margin of the first black matrix.

13. The display apparatus of claim 7, wherein the display substrate is a color filter substrate, and the opposite substrate is an array substrate, the array substrate comprises a gate line and a data line, the first black matrix is a gate line black matrix provided correspondingly to the gate line, and the second black matrix is a data line black matrix provided correspondingly to the data line; or
the display substrate is a color filter array substrate, and the opposite substrate is a transparent substrate, the color filter array substrate comprises a gate line and a data line, the first black matrix is a gate line black matrix provided correspondingly to the gate line, and the second black matrix is a data line black matrix provided correspondingly to the data line.

14. A manufacturing method of display substrate comprising:
forming a black matrix above a base substrate, the black matrix comprising a first black matrix and a second black matrix, the first black matrix and the second black matrix being intersected with each other; and
forming a photo spacer over the first black matrix, the first black matrix comprising a non-spacer part not provided correspondingly to the photo spacer and a spacer part provided correspondingly to the photo spacer, the non-spacer part having a line width smaller than width of the spacer part.

15. The manufacturing method of claim 14, wherein the step of forming a black matrix above a base substrate comprises:
forming a black matrix material layer above the base substrate;
applying photoresist on the black matrix material layer;
performing exposure on the photoresist through a mask so as to form a photoresist reserve part and a photoresist removal part, the mask comprising an open region and a light shading region;
performing development on the exposure photoresist to remove the photoresist removal part and reserve the photoresist reserve part;
etching the black matrix material layer above the base substrate to form the first black matrix and the second black matrix; and
stripping off the photoresist reserve part.
